(19) United States
(12) Patent Application Publication
(10) Pub. No.: US 2006/0243427 A1
(43) Pub. Date: Nov. 2, 2006

(54) Heat pipe heat sink and method for fabricating the same

(75) Inventors: Hironori Kitajima, Tsuchiura (JP); Hitoshi Sakayori, Tsukuba (JP); Tooru Kurosawa, Tsuchiura (JP); Yuuzou Shiraishi, Tsuchiura (JP); Katsumi Nomura, Tsuchiura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 11/384,341

(22) Filed: Mar. 21, 2006

(30) Foreign Application Priority Data
Apr. 28, 2005 (JP) 2005-132840

(51) Int. Cl. H05K 7/20

(52) U.S. Cl. 165/104.33; 361/700; 165/80.3

(57) ABSTRACT

A heat pipe heat sink and a method for making the same are disclosed. A heat pipe heat sink 1 has a heat block 2 which is heat exchangeably mounted to a heat exchange object, and the heat block 2 is composed of a first heat block unit 5 and a second heat block unit 6 for sandwiching a heat pipe 3. A first concave groove 5A and a second concave groove 6A are provided to form a pipe holding hole 2A between the first heat block unit 5 and the second heat block unit 6. The pipe holding hole 2A is configured as a space for accommodating one end of the heat pipe 3 by plastically deforming a cross section of the heat pipe 3 by sandwiching between the first heat block unit 5 and the second heat block unit 6. According to the heat pipe heat sink, reduction in cost, high heat transfer between the heat pipe and heat block, and stability in the heat pipe retention can be obtained.

The present application is based on Japanese Patent Application No. 2005-132840 filed on Apr. 28, 2005, the entire contents of which are incorporated herein by reference.

### BACKGROUND OF THE INVENTION

1. Field of the Invention

This invention relates to a heat pipe heat sink, in more particularly to a heat pipe heat sink for cooling electronic parts of a semiconductor device, etc. and a method for fabricating the same.

2. Description of the Related Art

By way of example only, a housing of a personal computer device accommodates a lot of electronic parts (heating elements) including an operation processing unit (for example, central processing unit “CPU”) to carry out data processing.

In such an electronic apparatus, an augmentation of Joule heat in the respective electronic parts becomes considerable in accordance with a high integration of the circuit and a speedup of the processing. Therefore, for preventing the electronic parts from a function loss due to an overheating of the electronic parts, a corrective means such as heat sink is provided for radiating a generated heat to a circumference of the electronic parts.

Conventional heat sinks are proposed by Japanese Patent No. 2613743 and Japanese Patent Laid-Open No. 2002-120033 (JP-A-2002-120033). The conventional heat sink comprises a cooling block having a plurality of passages as an electronic part mounting unit, a plurality of heat pipes each having apart installed in the respective passages, and a lot of fins positioned in parallel in a longitudinal direction of the heat pipes.

Such a heat sink can be fabricated by, for example, forming round holes in the cooling block (heat block) to provide a plurality of passages (pipe holding holes), inserting and fixing one end of the heat pipe in each of the passages, and joining the cooling fin for heat radiation with another end of the heat pipe.

In addition, a method of using the heat sink is as follows. A heat block made of metal is contacted to an electronic device radiating the heat, etc., directly or by using heat transfer grease. The heat transferred to the heat block is transferred via the heat pipe to the fin provided at another end of the heat pipe. The heat transferred to the fin is radiated in the air by natural cooling (air cooling without blower) or forced air cooling. Since the heat sink has the aforementioned heat transfer passage (heat radiation passage), a cooling performance (efficiency) of the heat sink is greatly influenced by a heat resistance between the electronic device and the heat block, a heat resistance between the heat block and the heat pipe, and a heat resistance between the heat pipe and the fins.

Accordingly, for realizing a heat pipe heat sink with high efficiency, it is desired to reduce the heat resistance at member contacting parts as much as possible.

However, in the conventional method for fabricating a heat sink by forming the round holes at the heat block, there are disadvantages in that a long processing time should be required for perforating (formation of the pipe holding holes) and that a fabrication cost becomes higher.

In addition, there is a further problem in the method for fabricating a heat sink by forming the round holes and inserting heat pipes into the heat block. In the fabricating process, so as to tolerate fluctuations of a diameter of the round hole and an outer diameter of the heat pipe due to processing tolerance, there are previously provided margins in designed dimensions of respective parts. Therefore, a gap is necessarily formed between the heat block (inner surfaces of the respective passages) and outer surfaces of the respective heat pipes. As a result, a step of filling respective gaps with a large quantity of solder is required, so as to stabilize thermal contact characteristics. At this time, in a state where the whole heat block is heated at a temperature higher than a melting temperature of the solder, the solder is often poured into the respective air gaps at plural points by hand work. Therefore, the fabrication cost becomes higher from a point of view of the working efficiency.

It can be also considered that the casting process of the solder is conducted by an automatic machine. However, for fabricating plural kinds of the heat sinks, exclusive automatic machines corresponding to various heat sinks are required. Therefore, there are disadvantages in that cost for installing equipments and maintenance thereof is increased.

For solving the aforementioned problems in the fabrication of the heat sink, e.g. complication of manufacturing steps, deterioration of working efficiency, etc., there is proposed a method comprising steps of forming pipe insertion grooves at two pieces of fixing plates, and engaging a heat pipe into the pipe insertion grooves for fixing the heat pipe, as shown in JP-A-2002-120033.

In the conventional method for fabricating a heat pipe heat sink, pipe insertion grooves each having a semicircular cross section are formed to provide a pipe holding hole. When the pipe insertion grooves are formed on surfaces of heat block units by cutting process, a processing cost becomes higher since a processing time is long. When the pipe insertion grooves are formed by extrusion molding process, manufacturing dispersions in shape and dimension may easily occur and a gap (vacant space) may be easily formed between an outer surface of the heat pipe and an inner surface of the pipe holding hole.

Formation of the gap at an interface leads to a reduction in a contact area of heat transfer, thereby increasing a heat resistance between the heat block and the heat pipe. As a result, there is a disadvantage in that a heat exchange efficiency between the heat block and the heat pipe is reduced, so that the heat pipe heat sink with high efficiency cannot be obtained.

In addition, when the gap is formed between the inner surface of the pipe holding hole and the outer surface of the heat pipe over a wide area, a retention force of the heat pipe by the heat block is deteriorated, so that a stability in holding the heat pipe cannot be obtained, for instance, the heat pipe becomes unstable or falls out.

### SUMMARY OF THE INVENTION

Accordingly, it is an object of the invention to provide a heat pipe heat sink with high heat radiation characteristics (efficiency) and high efficiency and a method for fabricating the same, by which a manufacturing cost can be reduced and a stability in holding the heat pipe can be obtained.

According to a first feature of the invention, a heat pipe heat sink, comprises:

a heat block comprising a pipe holding hole opened to at least one end, said heat block being mounted to an heat exchange object with which a heat exchange is possible;

a heat pipe which is plastically deformable and having one end held in the pipe holding hole of the heat block and another end exposed to outside of the heat block;

a plurality of heat transfer members mounted to the another end of the heat pipe which is exposed to the outside of the heat block, and positioned in parallel with each other in a longitudinal direction of the heat pipe;

a first heat block unit and a second heat block unit for sandwiching the heat pipe and constituting the heat block; and

a concave groove for forming the pipe holding hole, formed between the first heat block unit and the second heat block unit;

wherein the pipe holding hole accommodates the one end of the heat pipe that is plastically deformed to provide a cross section except a perfect circle by being sandwiched between the first heat block unit and the second heat block unit.

According to a second feature of the invention, in the heat pipe heat sink, a non-contact cross sectional length a of an outer periphery of the heat pipe held in the heat block to an inner periphery of the pipe holding hole is determined to satisfy an inequality of 0<a/A≦0.25, wherein A is a cross sectional length of the inner periphery of the pipe holding hole. Herein, a may be expressed as “a non-contact outer periphery length in the cross section of the heat pipe”, and A may be expressed as “an inner periphery length in the cross section of the pipe holding hole”.

According to a third feature of the invention, in the heat pipe heat sink, at least one of the first heat block unit and the second heat block unit is provided with a concave portion opened to a heat pipe contact side in an opened surface of the concave groove.

According to a fourth feature of the invention, in the heat pipe heat sink, at least one of the first heat block unit and the second heat block unit is provided with a convex portion protruding to a heat pipe contact side in an opened surface of the concave groove.

According to a fifth feature of the invention, in the heat pipe heat sink, at least one of the first heat block unit and the second heat block unit is provided with the concave groove.

According to a sixth feature of the invention, in the heat pipe heat sink, the concave groove is formed by interposing third heat block units between the first heat block unit and the second heat block unit.

According to a seventh feature of the invention, in the heat pipe heat sink, the heat pipe is bent at one or more point.

According to an eighth feature of the invention, in the heat pipe heat sink, either of the first heat block unit or the second heat block unit is divided into plural block elements.

According to a ninth feature of the invention, the heat pipe heat sink further comprises an interposing member provided between an inner periphery surface of the concave groove and an outer periphery surface of the heat pipe.

According to a tenth feature of the invention, a heat pipe heat sink, comprises:

a heat radiating member;

a heat block to be mounted to a heat exchange object, and comprising a first heat block unit, a second heat block unit and a pipe holding hole having a non-circular cross section; and

a heat pipe including one end held in the pipe holding hole and another end attached to the heat radiating member, the heat pipe being plastically deformable and conformed to the pipe holding hole by sandwiching between the first heat block unit and the second heat block unit.

According to an eleventh feature of the invention, a method for fabricating a heat pipe heat sink, which is provided with a heat block comprising a pipe holding hole opened to at least one end, said heat block being mounted to an heat exchange object with which a heat exchange is possible, a heat pipe which is plastically deformable and having one end held in the pipe holding hole of the heat block and another end exposed to outside of the heat block, and a plurality of heat transfer members mounted to the another end of the heat pipe which is exposed to the outside of the heat block, and positioned in parallel with each other in a longitudinal direction of the heat pipe,

the method for fabricating the heat pipe heat sink comprises steps of:

forming a first heat block unit and a second heat block unit for sandwiching the heat pipe and constituting the heat block;

providing a concave groove for forming the pipe holding hole between the first heat block unit and the second heat block unit;

installing the heat pipe in the pipe holding hole;

plastically deforming the heat pipe to provide a cross section except a perfect circle by being sandwiched between the first heat block unit and the second heat block unit;

wherein the pipe holding hole accommodates one end of the heat pipe that is plastically deformed by being sandwiched between the first heat block unit and the second heat block unit.

According to a twelfth feature of the invention, in the method for fabricating a heat pipe heat sink, a contact area between the concave groove and the heat pipe is 75% or less of an outer periphery surface area of the heat pipe at a portion covered by the first heat block unit and the second heat block unit at the step of installing the heat pipe, and the pipe holding hole contacts the heat pipe after deforming step such that a non-contact cross sectional length a of an outer periphery of the heat pipe held in the heat block to an inner periphery of the pipe holding hole satisfies an inequality of 0<a/A≦0.25, wherein A is a cross sectional length of the inner periphery of the pipe holding hole.

According to a thirteenth feature of the invention, a method for fabricating a heat pipe heat sink, comprises steps of:

forming a first heat block unit and a second heat block unit constituting a heat block;

providing a pipe holding hole with a non-circular cross section in the heat block;

installing one end of the heat pipe into the pipe holding hole;

attaching another end of the heat pipe to a heat radiating member; and

plastically deforming the heat pipe to conform to the pipe holding hole by sandwiching the heat pipe between the first heat block unit and the second heat block unit.

According to the present invention, it is possible to provide a heat pipe heat sink with the high heat radiation characteristics (efficiency) and high efficiency and a method for fabricating the same, by which the manufacturing cost can be reduced and the stability in holding the heat pipe can be obtained.

### BRIEF DESCRIPTION OF THE DRAWINGS

Preferred embodiment according to the invention will be described in conjunction with appended drawings, wherein:

FIGS. 1A and 1B are schematic illustrations showing a comparative example of a heat pipe heat sink, wherein FIG. LA is a perspective view thereof, and FIG. 1B is a partial cross sectional view thereof cut along C-C line;

FIGS. 2A and 2B are schematic illustrations showing a heat pipe heat sink in a first preferred embodiment according to the invention, wherein FIG. 2A is a perspective view thereof and FIG. 2B is a cross sectional view thereof cut along A-A line;

FIGS. 3A to 3C are cross sectional views showing a method for fabricating a heat pipe heat sink in the first preferred embodiment according to the invention;

FIGS. 4A and 4B are schematic illustrations showing a heat pipe heat sink in a second preferred embodiment according to the invention, wherein FIG. 4A is a perspective view thereof and FIG. 4B is a enlarged cross sectional view thereof cut along B-B line;

FIG. 5 is a cross sectional view of a heat pipe in a third preferred embodiment according to the invention;

FIG. 6 is a perspective view of a heat pipe heat sink in a third preferred embodiment according to the invention;

FIG. 7 is a perspective view of a heat pipe heat sink in a fourth preferred embodiment according to the invention; and

FIG. 8 is a perspective view of a heat pipe heat sink in a fifth preferred embodiment according to the present invention.

### DETAILED DESCRIPTION OF PREFERRED EMBODIMENTS

Next, a heat sink heat pipe in preferred embodiments according to the present invention will be explained in more detailed in conjunction with the appended drawings.

### Comparative Example

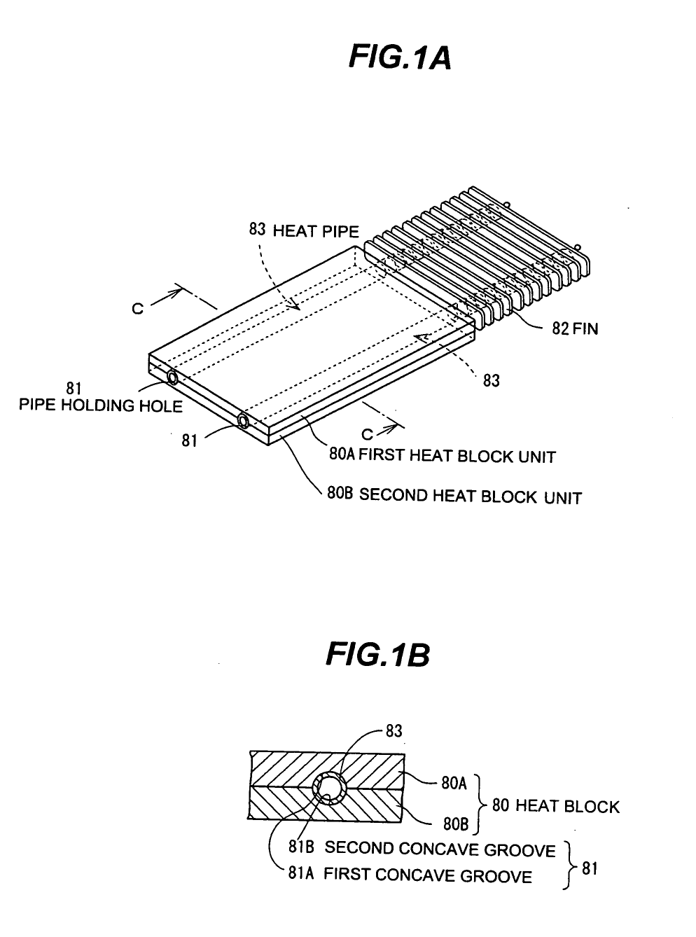

FIGS. 1A and 1B are schematic illustrations showing a comparative example of a heat pipe heat sink, wherein FIG. 1A is a perspective view thereof, and FIG. 1B is a partial cross sectional view thereof cut along C-C line.

The heat pipe heat sink in the comparative example is fabricated as follows. A first heat block unit 80A and a second heat block unit 80B are formed, then a first concave groove 81A and second concave groove 81B each having a semicircular cross section are formed on the first heat block unit 80A and the second heat block unit 80B respectively to provide pipe holding holes 81. Next, a heat pipe 83 having fins 82 is disposed in the first concave groove 81A and the second concave grooves 81B, and the heat pipe 83 is sandwiched between the first heat block unit BOA and the second heat block unit BOB.

However, in the aforementioned method for fabricating a heat pipe heat sink, the first and second concave grooves 81A, 81B each having a semicircular cross section may be formed by cutting the first and second heat block units BOA, BOB. From a point of view of congruence with an outer diameter of the heat pipe 83, the formation of the first and second concave grooves 81A, 81B by cutting process is more advantageous than the round hole process. However, the cutting process of the concave grooves causes a high processing cost since a processing time is long. When the first and second heat block units 80A, 80B provided with the first and second concave grooves 81A, 81B each having a semicircular cross section are formed by extrusion molding process, the processing cost may be reduced compared with the cutting process or round hole process. However, manufacturing dispersions in shape and dimension may easily occur, and as a result, a gap may be easily formed between an outer surface of the heat pipe 83 and an inner surface of the pipe holding hole 81. As described above, the formation of the gap at an interface between the heat pipe 83 and pipe holding hole 81 causes a reduction in a contact area of heat transfer, thereby increasing a heat resistance between the heat block 80 and the heat pipe 83. As a result, a heat exchange efficiency between the first and second heat block units 80A, 80B and the heat pipes 83 is reduced, so that there is a disadvantage in that the heat pipe heat sink with high efficiency cannot be obtained.

In addition, when the gap is formed between the inner surface of the pipe holding hole 81 and the outer surface of the heat pipe 83 over a wide area, a retention force of the heat pipes 83 by the heat block units 80A, 80B is deteriorated, so that there is a disadvantage in that a stability in holding the heat pipes 83 cannot be obtained, for instance, the heat pipes 83 become unstable or fall out.

### First Preferred Embodiment

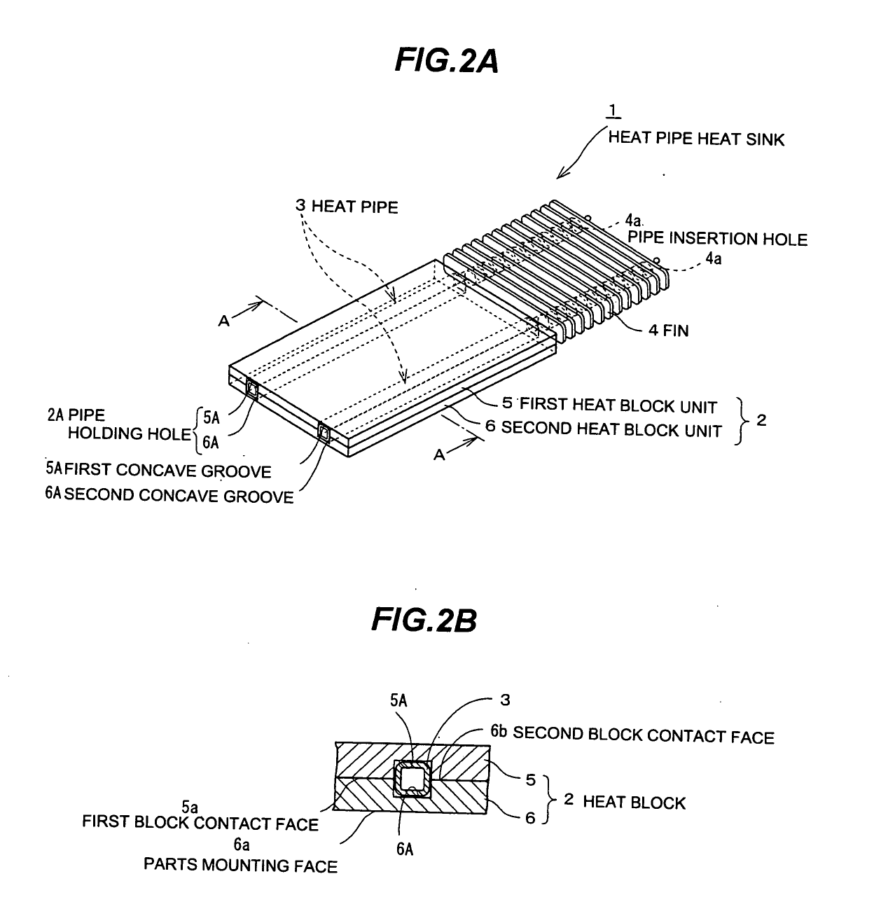

FIGS. 2A and 2B are schematic illustrations showing a heat pipe heat sink in a first preferred embodiment according to the invention, wherein FIG. 2A is a perspective view thereof and FIG. 2B is a partial cross sectional view thereof cut along A-A line.

(Whole Configuration of a Heat Sink)

In FIGS. 2A and 2B, a heat pipe heat sink 1 comprises a heat block (heat conducting member) 2 which receives a heat transferred from a heat exchange object (not shown), a heat pipe 3 contacting the heat block 2, and a plurality of fins (heat conducting members) 4 which radiate a heat transferred from the heat pipe 3 into the air. The number of the fins 4 is twelve in FIG. 2A. Herein, plate-like fins 4 are provided as cooling fins.

(Configuration of the Heat Block 2)

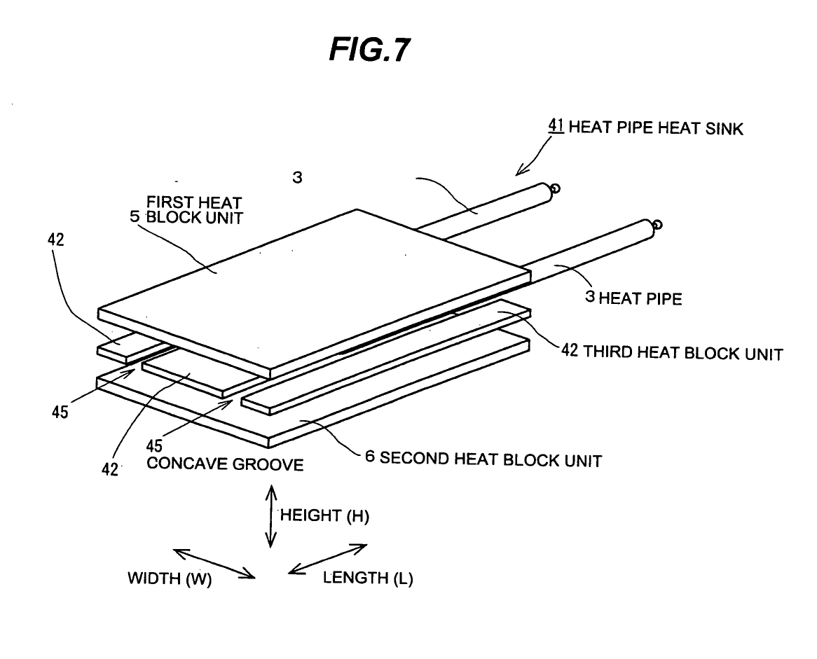

In FIG. 2, the heat block 2 comprises a first heat block unit 5 and a second heat block unit 6, which are separated in a block height (thickness) direction H, and a plurality of pipe holding holes 2A. Herein, “height (H), widthwise (W) and lengthwise (L) directions” used for explaining the configuration of the device mean three-dimensional directions as shown in FIG. 7.

The pipe holding holes 2A are positioned in parallel in a widthwise direction W (lateral direction on a horizontal surface), and opened to a lengthwise direction L (longitudinal direction on the horizontal surface). The number of the pipe holding holes 2A is two in FIG. 2A. As a material of the heat block 2, metal with high conductance of heat, such as copper, copper alloy, aluminum or aluminum alloy may be preferably used.

The first and second heat block units 5, 6 are respectively fixed to be adjacent to each other in the block height direction H, so as to hold the heat pipes 3 by sandwiching as shown in FIG. 2A. In addition, a parts mounting face of either one of the first and second heat block units 5, 6 is attached to the heat exchange object such as the electronic parts. For example, a parts mounting face 6a of the second heat block unit 6 is attached to the heat exchange object such that the parts mounting face 6a can receive and transfer the heat. As a method of fixing the first and second heat block units 5, 6, fixing method such as screw fastening, welding, solder joint or caulking may be used.

In the first heat block unit 5, first concave grooves 5A, 5A each having a rectangular cross section are positioned in parallel in the widthwise direction W (lateral direction on a horizontal surface), and opened to a first block contact face 5a of the first heat block unit 5 as shown in FIG. 2A. Similarly, in the second heat block unit 6, second concave grooves 6A, 6A each having a rectangular cross section are positioned in parallel in the widthwise direction W, and opened to a second block contact face 6b of the second heat block unit 6.

Each of the first and second concave grooves 5A, 6A has a width substantially equal to a diameter of the heat pipe 3 before plastic deformation, and has a depth smaller than a radius of the heat pipe 3 before plastic deformation.

Opened surfaces of the first and second heat block units 5, 6 are configured to correspond with each other to provide the pipe holding holes 2A, 2A, in a state where the first heat block unit 5 and the second heat block unit 6 are fixed (i.e. the heat pipes 3 are held by sandwiching). The pipe holding holes 2A, 2A are configured as vacant space parts for accommodating respective ends of the heat pipes 3. Each of the heat pipes 3 is plastically deformed to have a predetermined cross section except a perfect circle, by being sandwiched by the first and second heat block units 5 and 6. In other words, the heat pipe 3 is plastically deformed to conform to the pipe holding hole 2A having a non-circular cross section. Herein, concerning “the predetermined cross section except the perfect circle”, it is sufficient that the heat pipe 3 has a cross section except the perfect circle. Therefore, the cross section may be a polygon such as rectangular, hexagon, octagon, or may be an elliptical shape, or an oval-shape. The first and second grooves 5A, 6A may be processed by shaping processing (cutting process) or extruding process. The extruding process is desirable from the viewpoint of cost reduction in mass production. On the other hand, cost reduction in low production may be easily realized by the cutting process.

(Configuration of the Heat Pipe 3)

The heat pipe 3 is entirely composed of a cylindrical enclosure of a plastically deformable metal such as copper. A predetermined amount of hydraulic fluid (not shown) is sealed within the respective heat pipes 3. One end of the respective heat pipes 3 is exposed to outside of the heat block 2 and another end of the respective heat pipes 3 is pressured to contact to inside of the pipe holding holes 2A of the heat block 2. In addition, as a material of the heat pipe 3, metal such as copper or copper alloy, aluminum or aluminum alloy, titanium or titanium alloy, stainless steel may be preferably used.

As shown in FIG. 2B, an outer periphery of the heat pipe 3 held in the heat block 2 has a non-contact length a to an inner periphery of the pipe holding hole 2A when cut along a normal cross section (right section) of the heat pipe 3. The non-contact length a is determined to satisfy an inequality of 0<a/A≦0.25, wherein the normal cross section of the pipe holding hole 2A has an inner periphery length A. The non-contact length a may be determined to satisfy an equality of 0.05≦a/A≦0.25 or an inequality of 0.10≦a/A≦0.25. By determining the non-contact length a within these ranges, a contact area between an outer periphery surface of the heat pipe 3 and an inner periphery surface of the pipe holding hole 2A can be obtained sufficiently. Therefore, a heat transfer efficiency of the whole heat sink is not rate-controlled by a heat transfer resistance between the heat pipe 3 and the heat block 2, so that the heat pipe heat sink 1 with high efficiency can be obtained securely.

When an inequality a/A>0.25 is established, the contact area between the outer periphery surface of the heat pipe 3 and the inner periphery surface of the pipe holding hole 2A becomes small, so that the heat transfer resistance between the heat pipe 3 and the heat block 2 becomes large. As a result, a necessity to use a heat transfer member such as solder in the gaps becomes high. Therefore, it is preferable to set the non-contact length a in the above described ranges. In addition, even when the non-contact length a is set within the above described ranges, the heat transfer member may be interposed in a contacting part between the outer periphery surface of the heat pipe 3 and the inner periphery surface of the pipe holding hole 2A. The “contact” in this preferred embodiment includes a contact interposed by the heat transfer member as described above.

(Configuration of the Fin 4)

The fins 4 are respectively disposed in parallel with a longitudinal direction of the heat pipe 3. Each of the fins 4 comprises a plate-like member attached to an exposed portion of the heat pipe 3, and a pipe insertion hole 4A into which the heat pipe 3 is inserted. In addition, at an aperture periphery of the pipe insertion hole 4A, it is preferable to provide a ring-shaped attaching piece (not shown) integrally with the pipe insertion hole 4A to install the fin 4 to the heat pipe 3. In addition, as a material of the fin 4, metal such as copper or copper alloy, aluminum or aluminum alloy may be preferably used, however, the present invention is not limited thereto, and it is sufficient to use a material which radiates heat in the air with good efficiency.

(Method for Fabricating a Heat Pipe Heat Sink)

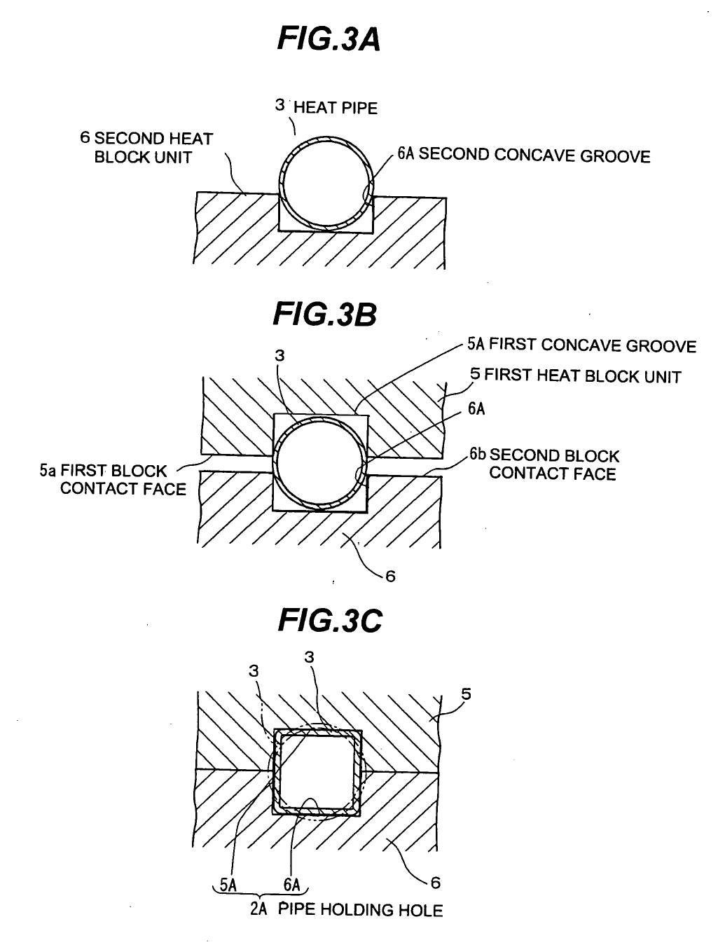

Next, a method for fabricating a heat pipe heat sink in the first preferred embodiment according to the present invention will be explained referring to FIGS. 3A to 3C.

FIGS. 3A to 3C are cross sectional views showing the method for fabricating a heat pipe heat sink in the first preferred embodiment according to the present invention, wherein FIG. 3A is a cross sectional view showing an installation state of a heat pipe, FIG. 3B is a cross sectional view showing first and second heat block units before sandwiching the heat pipe, and FIG. 3C is a cross sectional view showing the first and second heat block units after sandwiching the heat pipe.

According to the method of fabricating a heat pipe heat sink in the first preferred embodiment, steps of “forming the heat block units”, “recessing the heat block units” and “sandwiching the heat pipe” are sequentially conducted.

Since the aforementioned heat pipe heat sink 1 can be obtained by the method for fabricating a heat pipe heat sink in the first preferred embodiment, same reference numerals in FIGS. 2A and 2B are used for indicating similar parts in FIGS. 3A to 3C.

Steps of “forming the heat block units” and “recessing the heat block units”

The first heat block unit 5 having the first concave grooves 5A and the second heat block unit 6 having the second concave grooves 6A are formed to provide the pipe holding holes 2A for sandwiching the heat pipes 3, by the steps of forming the heat block units and recessing the heat block units.

At the step of forming the heat block units, the first heat block unit 5 and the second heat block unit 6 constituting the heat block 2 are respectively formed.

At the step of recessing the heat block units, the first concave grooves 5A, 5A are provided in the first heat block unit 5, and the second concave grooves 6A, 6A are provided in the second heat block unit 6, respectively, with a predetermined distance (interval) in the horizontal lateral direction (a widthwise direction W) as shown in FIG. 2A. The steps of forming the heat block units and recessing the heat block units may be conducted simultaneously by using a forming method such as extruding process.

The number of the concave grooves and the predetermined distance may be selected appropriately in accordance with desired radiation efficiency and radiation surface (block size). As a method of forming the concave groove, a cutting process for block materials or an extruding process for block materials having concave grooves may be preferably used. However, the present invention is not limited thereto, and it is sufficient to provide the concave groove in any manner as a result. The extruding process is desirable for cost reduction in the mass production, while the total cost in low production can be easily reduced by using the cutting process comparing with the extruding process.

Step of “sandwiching the heat pipe”

As shown in FIG. 3A, one end of (a part of) the heat pipe 3 before plastic deformation is disposed in each of the second concave grooves 6A of the second heat block unit 6.

Next, as shown in FIG. 3B, the first block contact face 5a is opposed to the second block contact face 6b, and the one end of (a part of) the heat pipe 3 is disposed in each of the first concave grooves 5A of the first heat block unit 5. In the first preferred embodiment, since the first concave grooves 5A of the first heat block unit 5 and the second concave grooves 6A of the second heat block unit 6 have rectangular cross sections, the first and second concave grooves 5A, 6A contact with the heat pipe 3 by a line contact (by a point contact in the normal cross section). In addition, in respective preferred embodiments to be described below, a contact area between the concave groove and the heat pipe when installed is 75% or less, 50% or less, or 25% or less of a periphery surface area of the heat pipe at a heat block covering part.

Subsequently, as shown in FIG. 3C, the heat pipe 3 is sandwiched by the first heat block unit 5 and the second heat block unit 6, such that the pipe holding hole 2A is formed by the first concave groove 5A of the first heat block unit 5 and the second concave groove 6A of the second heat block unit 6. At this time, while being restrained by bottom walls and sidewalls of the first and second concave grooves 5A, 6A (inner walls of the pipe holding hole 2A), the heat pipe 3 is plastically deformed in a pipe cross section (in a right section). As a result, a good contact between an inner periphery surface of the pipe holding hole 2A and an outer periphery surface of the heat pipe 3 is provided in vertical and lateral directions of the heat pipe 3 (directions shown in FIG. 3C).

As described above, in the first preferred embodiment (in a state of sandwiching the heat pipe 3), the heat pipe 3 contacts with the pipe holding hole 2A, such that an inequality of 0<a/A≦0.25 is satisfied, wherein a is a non-contact length of an outer periphery surface of the heat pipe 3 to the inner periphery surface of the pipe holding hole 2A in the normal cross section of the heat pipe 3, and A is an inner periphery length of the pipe holding hole 2A in the normal cross section. It is preferable that the heat pipe 3 contacts with the pipe holding hole 2A to satisfy a range expressed by the above inequality in all cross sections along the heat block covering part of the heat pipe 3. In the other preferred embodiments to be described below, the pipe holding hole 2A contacts the heat pipe 3 after completion of plastic deformation by sandwiching, such that the relationship between a and A satisfies an inequality 0<a/A≦0.25, 0.05≦a/A≦0.25, or 0.10≦a/A≦0.25. In all cross sections along the heat pipe 3 at the heat block covering part, it is desirable to contact to satisfy the area. It is preferable that the heat pipe 3 contacts with the pipe holding hole 2A to satisfy the range expressed by the above inequality in all cross sections along the heat block coating part of the heat pipe 3.

Thereafter, the first heat block unit 5 and the second heat block unit 6 are fixed to each other. As mentioned above, the method of fixing the first and second heat block units 5 and 6 such as screw fastening, welding, solder joint or caulking may be used.

As described above, the heat pipe heat sink 1 can be fabricated.

### Effect of the First Preferred Embodiment

According to the first preferred embodiment, following effects can be obtained.

(1) It is possible to absorb (permit) the manufacturing margins of the heat pipe 3 and the heat block units 5, 6, since the heat pipes 3 are held in the pipe holding holes 2A respectively with being plastically deformed. Since this configuration leads to an improvement in choice of design and an improvement of yield, the reduction in cost can be realized. Further, a gap (vacant space) is not formed over a wide area at the outer periphery surface of the heat pipe 3, between the inner periphery surface of the heat pipe 3 and the outer periphery surface of the pipe holding hole 2A. Therefore, the contact area of the heat transfer can be provided between the heat block 2 and the heat pipe 3. Still further, the outer periphery surface of the heat pipe 3 is crimped to the inner periphery surface of the pipe holding hole 2A, so that the contact (attachment) condition between the heat block 2 and the heat pipe 3 becomes good. According to this configuration, it is possible to reduce a heat resistance in the contact area, so that the heat pipe heat sink 1 with high efficiency can be obtained. In particular, even if the first and second concave grooves 5A, 6A of the first and second heat block units 5, 6 are formed by using the extruding process or the cutting process with loose processing precision (i.e. the admissible processing tolerance is large), the heat pipe heat sink 1 with the above effects can be obtained.

(2) The gap (vacant space) is not formed over the wide area between the outer surface of the heat pipe 3 and the inner surface of the pipe holding hole 2A along the outer periphery surface of the heat pipe 3, so that a retention force of the heat pipe 3 by the heat block 2 can be increased. In other words, the holding condition becomes stable.

(3) For filling the gap formed between the outer periphery surface of the pipe holding hole 2A and the inner periphery surface of the heat pipe 3 (corners of the pipe holding hole 2A) with a heat transfer material such as solder, the heat transfer material and the first and second heat block units 5, 6 may be heated at a temperature higher than a melting point of the heat transfer material, after interposing the heat transfer material between the heat pipe 3 and the first and second heat block units 5, 6. Therefore, comparing with a conventional filling method in which the heat transfer material such as solder is poured into the gaps by hand work, a working time can be shortened, and the reduction in cost can be realized in this point.

### Second Preferred Embodiment

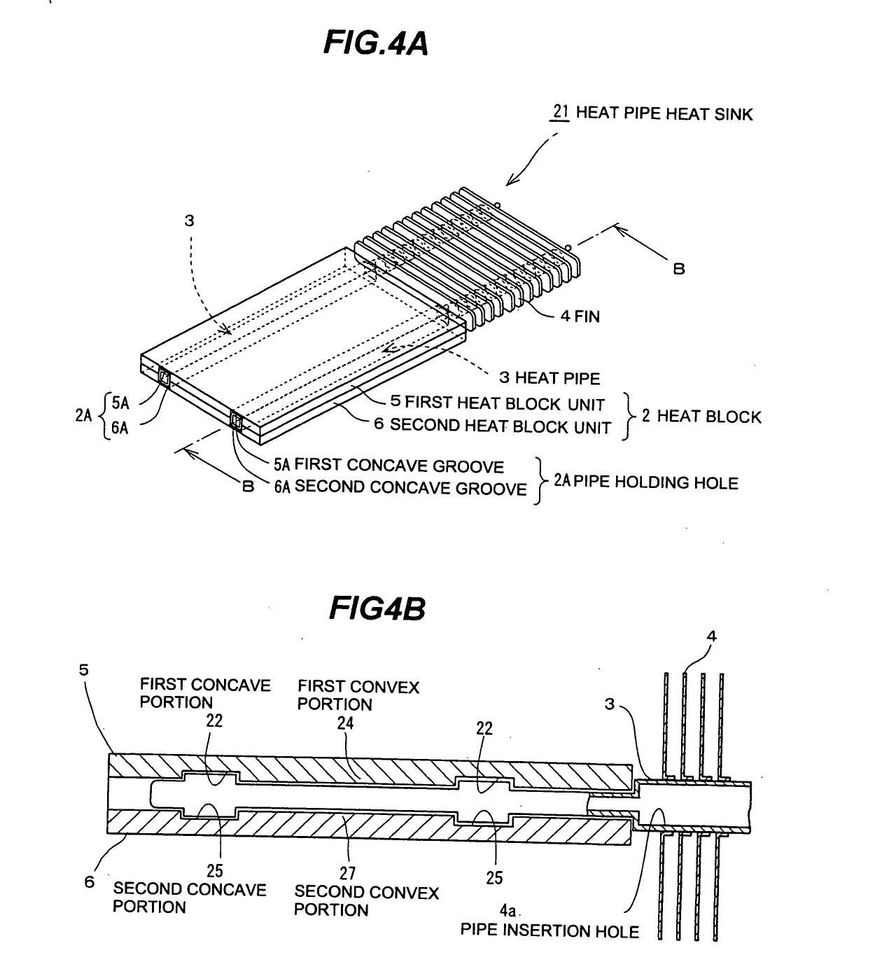

FIGS. 4A and 4B are schematic illustrations showing a heat pipe heat sink in a second preferred embodiment according to the present invention, wherein FIG. 4A is a perspective view thereof and FIG. 4B is a partial cross sectional view thereof cut along B-B line. Same reference numerals in FIGS. 2A and 2B are used for indicating identical or similar parts in FIGS. 4A and 4B, and detailed explanation thereof is omitted.

As shown in FIGS. 4A and 4B, a heat pipe heat sink 21 in the second preferred embodiment comprises a first heat block unit 5 and a second heat block unit 6. In the first heat block unit 5, an opened surface of a first concave groove 5A is provided with a first convex portion 24 protruded to a heat pipe contact side and first concave portions 22 opened to the heat pipe contact side. Similarly, in the second heat block unit 6, an opened surface of a second concave groove 6A is provided with a second convex portion 27 protruded to the heat pipe contact side and second concave portions 25 opened to the heat pipe contact side. A concave/convex portion may be formed such that the first and second convex portions 24, 27 are provided as a result of forming the first and second concave portions 22, 25. Alternatively, the concave/convex portion may be formed such that the first and second concave portions 22, 25 are provided as a result of forming the first and second convex portions 24, 27.

A plurality of the first convex portions 22 and second concave portions 24 and a plurality of the second concave portions 25 and the second convex portions 27 in the first and second concave grooves 5A, 6A may be respectively provided in a longitudinal direction L of the heat pipe 3. In addition, the concave/convex part may be formed at only either of the first heat block unit 5 or the second heat block unit 6.

### Effect of the Second Preferred Embodiment

According to the second preferred embodiment, following effects can be obtained in addition to the effects of the first preferred embodiment.

(1) By sandwiching the heat pipe 3 between the first heat block unit 5 and the second heat block unit 6, the heat pipe 3 can be plastically deformed in a pipe cross sectional (a right sectional) direction between the first and second concave portions 22 and 25, and between the first and second convex portions 24 and 27, respectively. These plastically deformed parts of the heat pipe 3 engage in the first and second concave portions 22, 25 and the first and second convex portions 24, 27, respectively. As a result, the retention force of the heat pipe 3 by the heat block 2 can be increased still more. In particular, it is possible to increase a resistance force (retention force) against a direction for pulling out the heat pipe 3 from the pipe holding hole 2A.

(2) The heat pipe 3 is deformed plastically between the first and second concave portions 22 and 25, and between the first and second convex portions 24 and 27, respectively. As a result, the manufacturing margins in a concave/convex processing can be absorbed, so that a holding configuration of the heat block 2 and the heat pipe 3 can be obtained securely.

### Third Preferred Embodiment

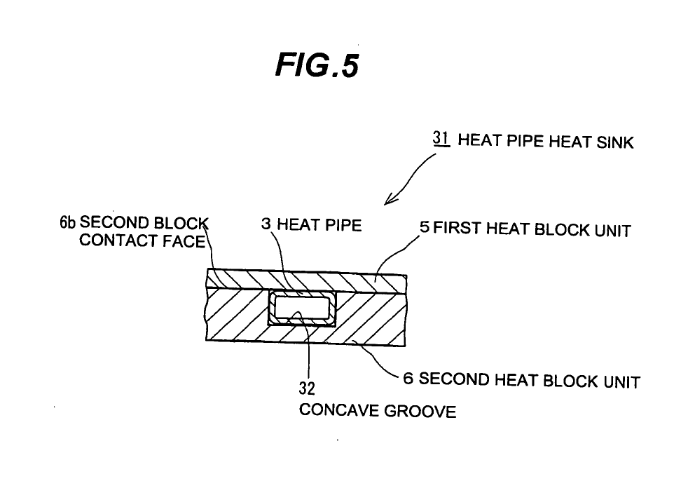

FIG. 5 is a cross sectional view of a heat pipe heat sink in a third preferred embodiment according to the invention. Same reference numerals in FIGS. 2A and 2B are used for indicating identical or similar parts in FIG. 5, and detailed explanation thereof is omitted.

As shown in FIG. 5, in a heat pipe heat sink 31 in the third preferred embodiment, only a second heat block unit 6 is provided with a concave groove 32 for forming a pipe holding hole 2A. Herein, the number of the concave groove 32 is one in FIG. 5.

In other words, the second heat block unit 6 is provided with the concave groove 32 opened to a block contact face 6b, while a first heat block unit 5 is made of a flat-plate block. In the third preferred embodiment, the first heat block unit 5 may be replaced with the second heat block unit 6 and vice versa in FIG. 5. Namely, the first heat block unit 5 may be provided with the concave groove 32, while the second heat block unit 6 may be made of the flat-plate block.

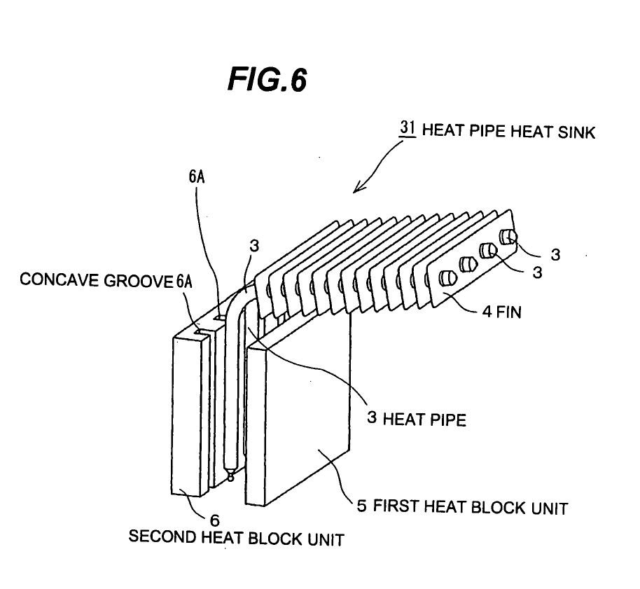

FIG. 6 is a perspective view of the heat pipe heat sink in the third preferred embodiment according to the invention. Same reference numerals in FIGS. 2A and 2B are used for indicating identical or similar parts in FIG. 6, and detailed explanation thereof is omitted.

As shown in FIG. 6, the heat pipe heat sink 31 in the third preferred embodiment comprises L-shaped heat pipes 3.

Accordingly, one end exposed to the outside (a fin mounting end portion) of the heat pipe 3 is formed to be bent against another end installed in the pipe holding hole 2A (concave groove 6A) with a substantially right angle.

FIG. 6 shows a configuration of the heat pipe heat sink 31 in which the heat pipe 3 is bent at only one point between the one end exposed to the outside (fin mounting end portion) and the heat block mounting end portion, however the invention is not limited thereto. The heat pipe 3 may be bent at plural points, and the bending angle is not limited to a substantially right angle.

As described above, when a space for the heat pipe 3 in a block surface direction is small, the one end exposed to the outside of the heat pipe 3 can be disposed in a space in a block thickness direction by bending the heat pipe 3, so that the space in the block thickness direction can be used effectively.

Further, in the other preferred embodiments according to the invention, the heat pipe 3 that is bent similarly to the third preferred embodiment may be used, and the heat pipe 3 without inflection may be used in the third preferred embodiment.

### Effect of the Third Preferred Embodiment

According to the third preferred embodiment, effects similar to those of the first preferred embodiment can be obtained, since the heat pipes 3 are plastically deformed in the concave grooves 32 (pipe holding holes 2A) respectively by sandwiching the heat pipes 3 between the first heat block unit 5 and the second heat block unit 6. Further, the reduction of processing cost can be expected, since it is sufficient to conduct the concave groove forming process only for either of the first heat block unit 5 or the second heat block unit 6.

### Fourth Preferred Embodiment

FIG. 7 is a perspective view of a heat pipe heat sink in the fourth preferred embodiment according to the present invention. Same reference numerals in FIGS. 2A and 2B are used for indicating identical or similar parts in FIG. 7, and detailed explanation thereof is omitted. Further, in FIG. 7, the fins 4 illustrated in FIGS. 2A, 3A, 3B, and 6 are omitted.

As shown in FIG. 7, a heat pipe heat sink 41 in the fourth preferred embodiment comprises a plurality of third heat block units 42, and is provided with concave grooves 45 to form pipe holding holes 2A.

Accordingly, as shown in FIG. 7, the third heat block units 42 are disposed in parallel with each other with a predetermined distance (interval) in a horizontal lateral direction W (widthwise direction), and the third heat block units 42 are interposed between the first heat block unit 5 and the second heat block unit 6, such that the concave groove 45 is formed between two pieces of the third heat block units 42. Herein, the first and second heat block units 5, 6 are made of flat-plate blocks without concave groove.

### Effect of the Fourth Preferred Embodiment

According to the fourth preferred embodiment, following effects can be obtained in addition to the effects of the first preferred embodiment.

(1) Since the concave groove 45 for forming the pipe holding hole 2A is formed by interposing the third heat block units 42 between the first heat block unit 5 and the second heat block unit 6, it is not necessary to conduct the groove forming process to the first, second and third heat block units 5, 6, and 42. Therefore, the reduction in cost can be expected.

### Fifth Preferred Embodiment

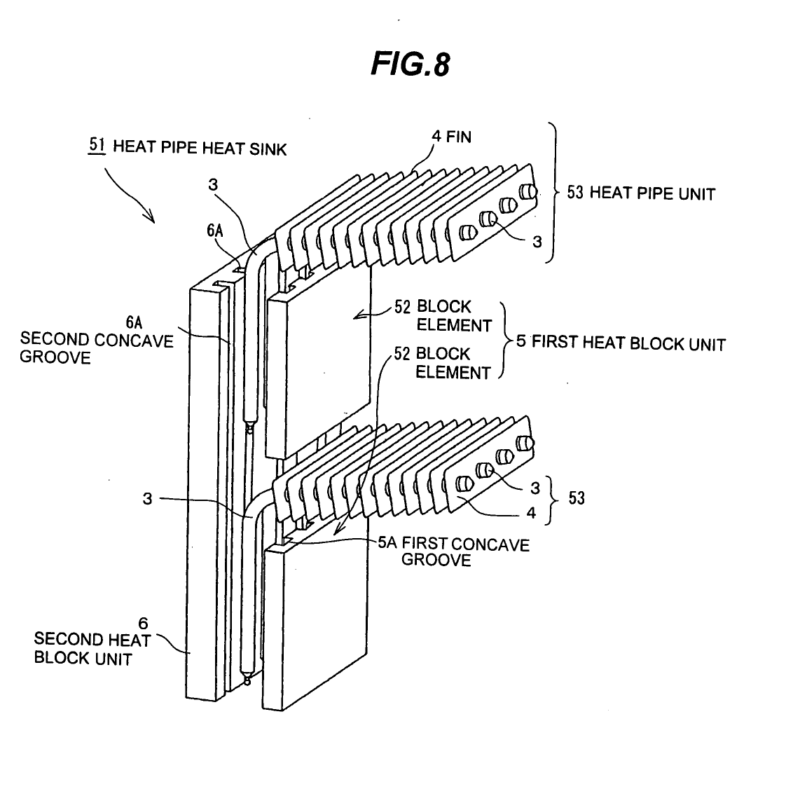

FIG. 8 is a perspective view of a heat pipe heat sink in a fifth preferred embodiment according to the invention. Same reference numerals in FIGS. 2A and 2B are used for indicating identical or similar parts in FIG. 8, and detailed explanation thereof is omitted.

As shown in FIG. 8, a heat pipe heat sink 51 in the fifth preferred embodiment is configured such that either of a first heat block unit 5 or a second heat block unit 6 is divided. This type of heat pipe heat sink is particularly effective, when large heat blocks or a lot of heat pipes are required or a plurality of heat pipe heat sinks installed in adjacent positions are gathered in one, in accordance with a position of a heat exchange object (layout of the electronic parts to be cooled off in an electronic apparatus) and a heating value of electronic parts (i.e. heat radiation).

In FIG. 8, the first heat block unit 5 is divided into two pieces of block elements 52. The block elements 52 comprise a first concave groove 5A to be opened to a block contact face (the second heat block unit side) respectively, and are provided in parallel with each other in a longitudinal direction of the concave grooves.

In FIG. 8, the second heat block unit 6 comprises concave grooves 6A, and is made of a block commonly used for two pieces of the block elements 52, and configured such that two pieces of the heat pipe units 53 (combination of the heat pipe 3 and a fin 4) are sandwiched by the second heat block unit 6 and two pieces of the block elements 52 (constituting the first heat block unit 5). Since the concave groove 6A is relatively long, the concave groove 6A can be formed inexpensively when the extruding process is used.

In the fifth preferred embodiment, there is described the heat pipe heat sink in which the pipe holding hole 2A is formed by the concave groove 5A of the first heat block unit 5 and the concave groove 6A of the second heat block unit 6. However, similarly to the third preferred embodiment, the pipe holding hole 2A may be formed only by the concave groove 6A.

### Effect of the Fifth Preferred Embodiment

According to the fifth preferred embodiment, following effects can be obtained in addition to the effects of the first preferred embodiment.

Since the second heat block unit 6 is a heat block commonly used by the two heat pipe units 53, 53, the number of parts can be reduced, so that reduction in assembling cost and manufacturing cost can be expected. Further, a plurality of heat pipe heat sinks installed at adjacent positions in the electronic apparatus can be gathered in one. For a user, a further reduction in cost can be realized compared to a case where plural heat pipe heat sinks are purchased and installed.

Further, there is described that the number of the block elements 52 is determined as two in the fifth preferred embodiment, however, the number of the block elements 52 may be three or more.

As described above, a heat pipe heat sink of the present invention is explained according to the first to fifth preferred embodiments as things mentioned above, however, the present invention is not limited thereto. The present invention can be realized in various embodiments within a scope, which does not go beyond the subject matter of the present invention. For example, following variations are also possible.

(1) In the above described preferred embodiments, the heat transfer material such as solder is used for filling the gap between the inner periphery surface of the pipe holding hole 2A and the outer periphery surface of the heat pipe 3, which is formed by sandwiching the heat pipe 3 by the first heat block unit 5 and the second heat block unit 6. However, the present invention is not limited thereto, and heat transfer adhesive or heat transfer grease may be used as the heat transfer material. In addition, an interposing member such as solder plating materials, tin plating materials, soft metal (metal softer than the heat block and the heat pipe) may be interposed between the inner surface of the pipe holding hole 2A and the outer surface of the heat pipe 3.

(2) In the above described preferred embodiments, the pipe holding holes 2A are rectangular slots. However, the present invention is not limited thereto. It is sufficient that the pipe holding hole 2A has a predetermined cross section except a perfect circle, i.e. non-circular cross section, and the pipe holding hole 2A may be hexagon hole, octagon hole, elliptical hole, or long hole. In addition, if the concave grooves of the first heat block unit 5 and the second heat block unit 6 have a substantially equal width, the concave grooves having different cross sections may be combined. For example, the concave groove having a semi-circular cross section of the first heat block unit 5 may be combined with the concave groove having a rectangular cross section of the second heat block unit 6.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching herein set forth.

What is claimed is:

1. A heat pipe heat sink, comprising:
a heat block comprising a pipe holding hole opened to at least one end, said heat block being mounted to an heat exchange object with which a heat exchange is possible;
a heat pipe which is plastically deformable and having one end held in the pipe holding hole of the heat block and another end exposed to outside of the heat block;
a plurality of heat transfer members mounted to the another end of the heat pipe which is exposed to the outside of the heat block, and positioned in parallel with each other in a longitudinal direction of the heat pipe;
a first heat block unit and a second heat block unit for sandwiching the heat pipe and constituting the heat block; and
a concave groove for forming the pipe holding hole, formed between the first heat block unit and the second heat block unit;
wherein the pipe holding hole accommodates the one end of the heat pipe that is plastically deformed to provide a cross section except a perfect circle by being sandwiched between the first heat block unit and the second heat block unit.

2. The heat pipe heat sink, according to claim 1, wherein:
a non-contact cross sectional length a of an outer periphery of the heat pipe held in the heat block to an inner periphery of the pipe holding hole is determined to satisfy an inequality of 0<a/A≦0.25, wherein A is a cross sectional length of the inner periphery of the pipe holding hole.

3. The heat pipe heat sink, according to claim 1, wherein:
at least one of the first heat block unit and the second heat block unit is provided with a concave portion opened to a heat pipe contact side in an opened surface of the concave groove.

4. The heat pipe heat sink, according to claim 1, wherein:
at least one of the first heat block unit and the second heat block unit is provided with a convex portion protruding to a heat pipe contact side in an opened surface of the concave groove.

5. The heat pipe heat sink, according to claim 1, wherein:
at least one of the first heat block unit and the second heat block unit is provided with the concave groove.

6. The heat pipe heat sink, according to claim 1, wherein:
the concave groove is formed by interposing third heat block units between the first heat block unit and the second heat block unit.

7. The heat pipe heat sink, according to claim 1, wherein:
the heat pipe is bent at one or more point.

8. The heat pipe heat sink, according to claim 1, wherein:
either of the first heat block unit or the second heat block unit is divided into plural block elements.

9. The heat pipe heat sink, according to claim 1, further comprising:
an interposing member provided between an inner periphery surface of the concave groove and an outer periphery surface of the heat pipe.

10. A heat pipe heat sink, comprising:
a heat radiating member;
a heat block to be mounted to a heat exchange object, and comprising a first heat block unit, a second heat block unit and a pipe holding hole having a non-circular cross section; and
a heat pipe including one end held in the pipe holding hole and another end attached to the heat radiating member, the heat pipe being plastically deformable and conformed to the pipe holding hole by sandwiching between the first heat block unit and the second heat block unit.

11. A method for fabricating a heat pipe heat sink, which is provided with a heat block comprising a pipe holding hole opened to at least one end, said heat block being mounted to an heat exchange object with which a heat exchange is possible, a heat pipe which is plastically deformable and having one end held in the pipe holding hole of the heat block and another end exposed to outside of the heat block, and a plurality of heat transfer members mounted to the another end of the heat pipe which is exposed to the outside of the heat block, and positioned in parallel with each other in a longitudinal direction of the heat pipe,
the method for fabricating the heat pipe heat sink comprising steps of:
forming a first heat block unit and a second heat block unit for sandwiching the heat pipe and constituting the heat block;
providing a concave groove for forming the pipe holding hole between the first heat block unit and the second heat block unit;
installing the heat pipe in the pipe holding hole;
plastically deforming the heat pipe to provide a cross section except a perfect circle by sandwiched between the first heat block unit and the second heat block unit;
wherein the pipe holding hole accommodates one end of the heat pipe that is plastically deformed by being sandwiched between the first heat block unit and the second heat block unit.

12. The method for fabricating a heat pipe heat sink, according to claim 11, wherein:
a contact area between the concave groove and the heat pipe is 75% or less of an outer periphery surface area of the heat pipe at a portion covered by the first heat block unit and the second heat block unit at the step of installing the heat pipe, and the pipe holding hole contacts the heat pipe after deforming step such that a non-contact cross sectional length a of an outer periphery of the heat pipe held in the heat block to an inner periphery of the pipe holding hole satisfies an inequality of 0<a/A≦0.25, wherein A is a cross sectional length of the inner periphery of the pipe holding hole.

13. A method for fabricating a heat pipe heat sink, comprising steps of:
forming a first heat block unit and a second heat block unit constituting a heat block;
providing a pipe holding hole with a non-circular cross section in the heat block;
installing one end of the heat pipe into the pipe holding hole;
attaching another end of the heat pipe to a heat radiating member; and
plastically deforming the heat pipe to conform to the pipe holding hole by sandwiching the heat pipe between the first heat block unit and the second heat block unit.
